(19) United States
(12) Patent Application Publication
(10) Pub. No.: US 2019/0094441 A1
(43) Pub. Date: Mar. 28, 2019

(54) DISPLAY DEVICE

(71) Applicant: Emotech Ltd., London (GB)

(72) Inventors: Hongbin ZHUANG, London (GB); Szu-Hung LEE, London (GB); Martin RIDDIFORD, London (GB); Rob BUTTERWORTH, London (GB); Douglas MORTON, London (GB); Patrick HUNT, London (GB)

(21) Appl. No.: 16/141,594

(22) Filed: Sep. 25, 2018

(30) Foreign Application Priority Data
Sep. 25, 2017 (GB) 1715466.7

(51) Int. Cl. F21V 8/00

(52) U.S. Cl. CPC G02B 6/0001; H01L 25/13

(57) ABSTRACT

A display device comprises first, second and third layers. The first layer is spaced apart from the second layer. The third layer is arranged between the first and second layers. The first layer comprises a display surface facing away from the second layer. The display surface is arranged to provide a display output. The second layer comprises a plurality of light-emitting elements. The third layer of the display device comprises a plurality of discrete guide channels. Each guide channel in the plurality of guide channels is arranged to guide light travelling from a respective light-emitting element in the plurality of light-emitting elements to the display surface. Different guide channels in the plurality of guide channels have different channel lengths.

### CROSS-REFERENCE TO RELATED APPLICATIONS

This application claims priority to United Kingdom Application No. GB 1715466.7 filed Sep. 25, 2017, under 35 U.S.C. § 119(a), which is incorporated by reference in its entirety.

### BACKGROUND OF THE INVENTION

### Field of the Invention

The present invention relates to a display device.

### Description of the Related Technology

Display devices are used in many applications. A display device may generate a visual display on a display surface. The visual display may be generated by one or more light sources of the display device. The one or more light sources may, for example, be internal to the display device. In some cases, the visual display is generated by an array of discrete light sources such as light-emitting diodes (LEDs). Producing a display output with desired visual properties may present challenges when using an array of discrete light sources. The visual properties of the display output may be a factor in user experience.

Display surfaces, that is, surfaces via which a display is output, may be planar or non-planar. Producing a display output having the desired visual properties may be a particular consideration when non-planar display surfaces are used.

### SUMMARY

According to an aspect of the present invention, there is provided a display device comprising a first layer and a second layer, the first layer comprising a display surface facing away from the second layer, the display surface being arranged to provide a display output, the second layer comprising a plurality of light-emitting elements, wherein the display device comprises a plurality of discrete guide channels, each guide channel in the plurality of guide channels being arranged to guide light travelling from a respective light-emitting element in the plurality of light-emitting elements to the display surface.

Further features and advantages will become apparent from the following description, given by way of example only, which is made with reference to the accompanying drawings.

### BRIEF DESCRIPTION OF THE DRAWINGS

FIG. 1A shows a schematic cross-sectional view of an example of a display device in accordance with an embodiment of the present invention;

FIG. 1B shows a schematic plan view of a part of the display device shown in FIG. 1A;

FIG. 2 shows a schematic exploded view of an example of a robot in accordance with an embodiment of the present invention;

FIG. 3A shows a schematic cross-sectional view of the robot shown in FIG. 2;

FIG. 3B shows a schematic cross-sectional view of the robot shown in FIG. 2;

FIG. 4 shows a schematic exploded view of another example of a robot in accordance with an embodiment of the present invention;

FIG. 5A shows a schematic cross-sectional view of the robot shown in FIG. 4;

FIG. 5B shows a schematic cross-sectional view of the robot shown in FIG. 4;

FIG. 6 shows a schematic cross-sectional view of the robot shown in FIG. 4; and

FIG. 7 shows a perspective view of another example of a robot in accordance with an embodiment of the present invention.

### DETAILED DESCRIPTION OF CERTAIN INVENTIVE EMBODIMENTS

Like items are denoted herein using like reference signs but incremented by different multiples of 100 in different figures.

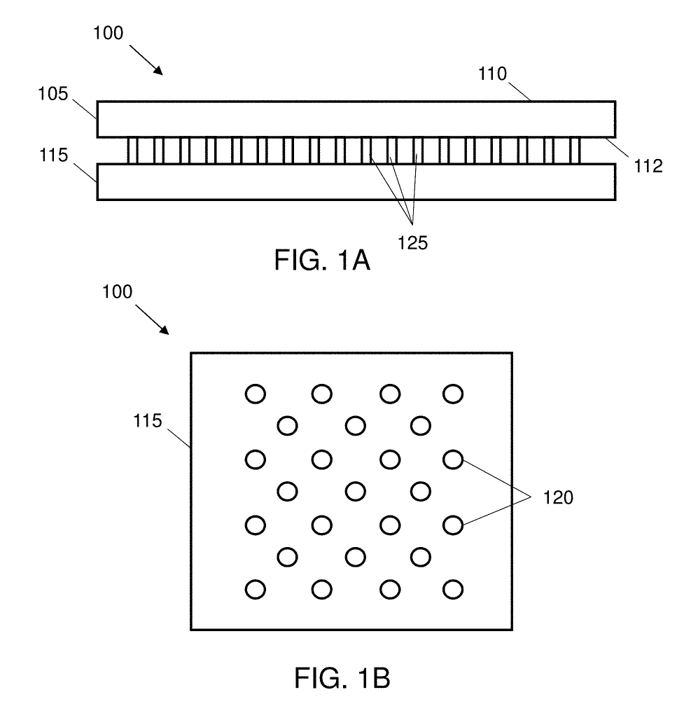

Referring to FIG. 1A, there is shown schematically an example of a display device 100 in cross-sectional view. The display device 100 is an electronic device that is capable of outputting a visual display. For example, a visual display may be output to the environment of the display device 100. The display device 100 may be an interactive device, that is, a device with which a user may interact.

In some examples described in more detail below, the display device 100 is comprised in a robot. In some examples, the display device 100 comprises a robot. A robot may be considered to be a guided agent. A robot may be guided by one or more computer programs and/or electronic circuitry. A robot may be guided by an external control device or the control may be embedded within the robot. A robot may be configured to interact with humans and/or an environment. A robot may or may not be configured to move. It will be understood however that the display device 100 may be of a different type. For example, the display device 100 may be comprised in a loudspeaker such as a smart speaker. A smart speaker is a type of loudspeaker having functionality beyond audio playback. For example, a smart speaker may be configured to initiate telephone calls, interact with users, access one or more data communications networks, or control other devices. A robot may be arranged to perform some or all of the functionality of a smart speaker. The display device 100 may be or be comprised in another type of computing device, for example a smart device, mobile device or audiovisual device such as a television or monitor. A robot may be considered to be a smart device. An example of a smart device is a smart home device, otherwise referred to as a home automation device. A smart home device may be arranged to control aspects of an environment including, but not limited to, lighting, heating, ventilation, telecommunications systems and entertainment systems. A robot as described in the examples below may be arranged to perform some or all of the functionality of a smart home device.

The display device 100 comprises a first layer 105. In this example, the first layer 105 is an outer layer of the display device 100. For example, the first layer 105 may comprise an outer shell of a robot. The first layer 105 may be the outermost layer of several layers of the device 100. The first layer 105 may be a closest layer to the environment of the device 100. The first layer 105 comprises a display surface 110. In this example, the display surface 110 is an outer surface of the first layer 105. The first layer 105 also comprises a further surface 112. The further surface 112 is an inner surface of the first layer 105. The display surface 110 is arranged to provide a display output. The display output may be a visual output. For example, the device 100 may interact with a user by generating a visual output displayed on the display surface 110. The visual output may vary based on a user interaction.

In some examples, at least part of the first layer 105 is translucent. As such, light may pass through at least part of the first layer 105 to reach the environment of the device 100.

In some examples, the first layer 105 comprises a light diffuser. A light diffuser is arranged to diffuse or scatter light in some manner. Use of a light diffuser may result in relatively soft light being displayed on the display surface 110.

In some examples, the optical properties of the first layer 105 are selected and/or tuned so as to conform to a desired output on the display surface 110. Examples of such optical properties include, but are not limited to, transmittance, reflectance and absorption of light having various wavelengths or colors.

In some examples, characteristics of the first layer 105 such as the color or material of the first layer 105 are determined based on the optical properties resulting from such characteristics. For example, the material from which the first layer 105 is formed may be selected based on the desired translucency and/or diffusivity of the given material. In some examples, the outer surface of the first layer 105, namely the display surface 110, is treated and/or painted in order to produce a visual output with desired characteristics. Different treatments may result in display outputs having different visual effects or properties.

In some examples, different portions of the first layer 105 may have different optical properties. For example, different portions of the first layer 105 may be formed from differently colored materials. Providing different portions of the first layer 105 with different optical properties may be desirable in order to generate a visual output with varying characteristics across the display surface 110.

The device 100 also comprises a second layer 115. The second layer 115 comprises a plurality of light-emitting elements 120, as depicted in FIG. 1B. An example of a light-emitting element is a light-emitting diode (LED). For convenience and brevity, light-emitting elements are referred to herein as LEDs, it being understood that other forms of light-emitting elements may be used in other examples. The plurality of LEDs 120 may be arranged in an array or matrix configuration. The plurality of LEDs 120 may be evenly spaced apart or unevenly spaced apart. Different LEDs in the plurality of LEDs 120 may emit light of different colors. The second layer 115 may comprise a planar surface. In other words, the second layer 115 may be substantially flat. As such, the plurality of LEDs 120 may be disposed on the planar surface. In some examples, the second layer 115 comprises a printed circuit board (PCB) to which the plurality of LEDs 120 are coupled, for example via soldering.

The second layer 115 is separate from the first layer 105. In this example, the first layer 105 and the second layer 115 are spaced apart. In other words, physical space exists between the first layer 105 and the second layer 115. In other examples, however, the first layer 105 and the second layer 115 are in contact. For example, at least part of the inner surface 112 of the first layer 105 may be contiguous with at least part of the second layer 115.

The display surface 110 of the first layer 105 faces away from the second layer 115. In other words, the second layer 115 is positioned behind the first layer 105 with reference to a user of the device 100, and faces the inner surface 112 of the first layer 105. The display surface 110 faces away from the second layer 115 such that a line normal to the display surface 110 has a component that is perpendicular to the plane of the second layer 115 and that extends away from the second layer 115 (e.g. upwards in FIG. 1A). The second layer 115 is an inner layer of the device 100 relative to the first layer 105.

Therefore, there is physical space between the second layer 115 containing the plurality of LEDs 120 and the display surface 110. Such physical space may correspond to the thickness of the first layer 105, or, where the first layer 105 and second layer 115 are spaced apart, the physical space may correspond to the combined thickness of the first layer 105 and the intermediate spacing between the first layer 105 and the second layer 115. Arranging the plurality of LEDs 120 at a distance behind the display surface 110 may facilitate a more pleasing visual output and user experience, as the particular shape and/or visual detail of a given LED may not be visible to a user during operation. For example, a user may not be able to identify that the visual output displayed on the display surface 110 is in fact caused by LEDs.

The device 100 comprises a plurality of discrete guide channels 125. Each guide channel in the plurality of guide channels 125 is arranged to guide light travelling from a respective LED in the plurality of LEDs 120 to the display surface 110. In other words, a given LED has a corresponding guide channel which guides light emitted from the given LED only. Providing a plurality of discrete guide channels 125 to guide light from respective LEDs reduces crosstalk and/or interference between light emitted from different LEDs, for example neighboring LEDs. The discrete guide channels 125 may also reduce saturation of light displayed on the display surface 110. As such, the guide channels 125 may improve a visual quality of the display output, and thus improve a user experience. The displayed output generated by the device 100 may therefore comprise, for each LED, a pronounced and well-defined dot or spot. A given dot displayed on the display surface 110 may be the same color as that of the corresponding LED.

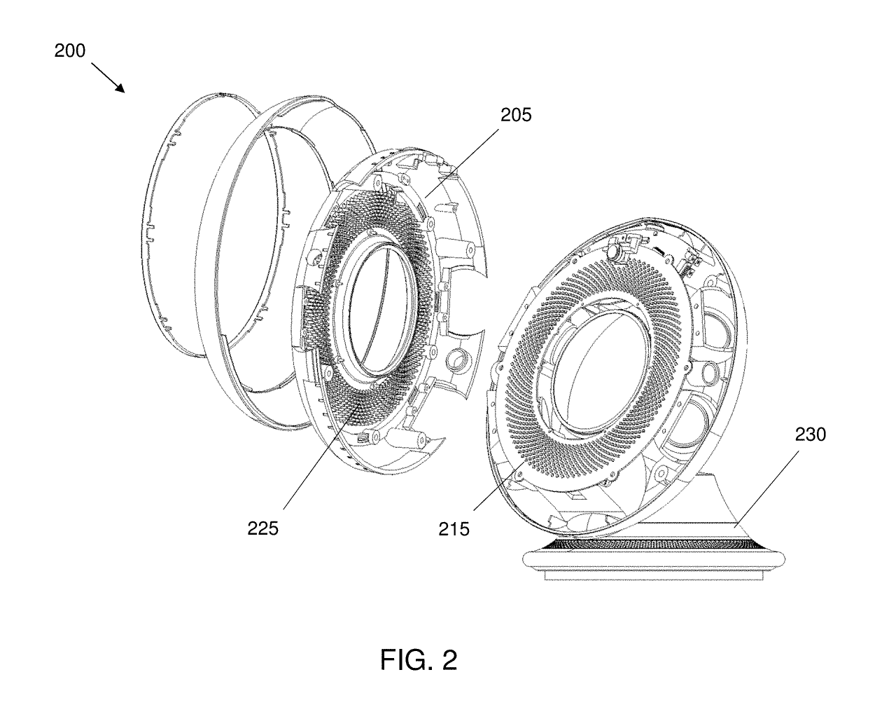

Referring to FIG. 2, there is shown schematically an exploded view of an example of a robot 200. The robot 200 comprises a first layer 205, a second layer 215 and guide channels 225. The first layer 205, second layer 215 and guide channels 225 form a display device such as display device 100 described above. The robot 200 also comprises a base portion 230. In this example, the robot 200 is toroidal in shape, it being understood that other shapes may be used in other examples.

The robot 200 may be an autonomous robot. An autonomous robot may be considered to be a robot that performs functions with a relatively high degree of autonomy or independence compared to non-autonomous robots.

The robot 200 may be a social robot. A social robot may be considered to be an autonomous robot that interacts with one or more other entities based on social behaviors and/or social rules associated with its role. Examples of such entities include, but are not limited to, users or other agents.

In this example, the second layer 215 is annular or ring-shaped. The second layer 215 may be formed into other shapes in other examples. For example, the second layer 215 may be rectangular or circular. In some examples, the second layer 215 is free-form. A free-form second layer 210 may be manufactured and/or modified according to any desired shape.

In this example, the plurality of guide channels 225 and the first layer 205 are integrally formed. In other words, the plurality of guide channels 225 and the first layer 205 are formed in the same body. For example, the plurality of guide channels 225 may be built into the outer casing of the robot 200.

In this example, the plurality of guide channels 225 comprises a plurality of spaced apart elongate members. The elongate members may be referred to as ‘light pipes’. In some examples, each light pipe is solid. That is, light from a given LED may be guided through the solid light pipe corresponding to the given LED. Light may be guided through a given light pipe by reflecting the light off the inner surfaces of the light pipe, for example via total internal reflection. As such, the light pipes may be formed from a translucent material. In other examples, each light pipe is hollow. That is, light from a given LED may be guided through a space between the internal walls of the corresponding light pipe.

In some examples, a bottom surface of each light pipe is polished. The bottom surface of light pipe is the surface that is closest to the corresponding LED for the light pipe. Polishing the bottom surface of a light pipe enables light emitted from an LED to enter the light pipe and thus facilitates the guiding of the light to the display surface 210.

In some examples, a given surface of each light pipe is formed of a white colored material or is treated with a white colorant. An example of a colorant is a paint. The given surface may be an inner surface. Treating the given surface with a white colorant may enhance the resulting brightness of the display output, due to the relatively high reflectance of white surfaces.

In some examples, the given surface of each light pipe is treated with a silver colorant and/or a black colorant. Treating the given surface with a silver or black colorant may reduce crosstalk between light emitted from neighboring LEDs. In some examples, the given surface is treated twice, firstly with a white colorant and secondly with silver or black colorant. Treating the given surface twice may result in a bright display output on the display surface 210 with relatively little crosstalk between light from different LEDs.

When the first layer 205 is placed over the second layer 215, for example when the robot 200 is in use, each guide channel 225 is positioned above and/or around a different LED. As such, light from each LED is individually and separately guided to the display surface 210.

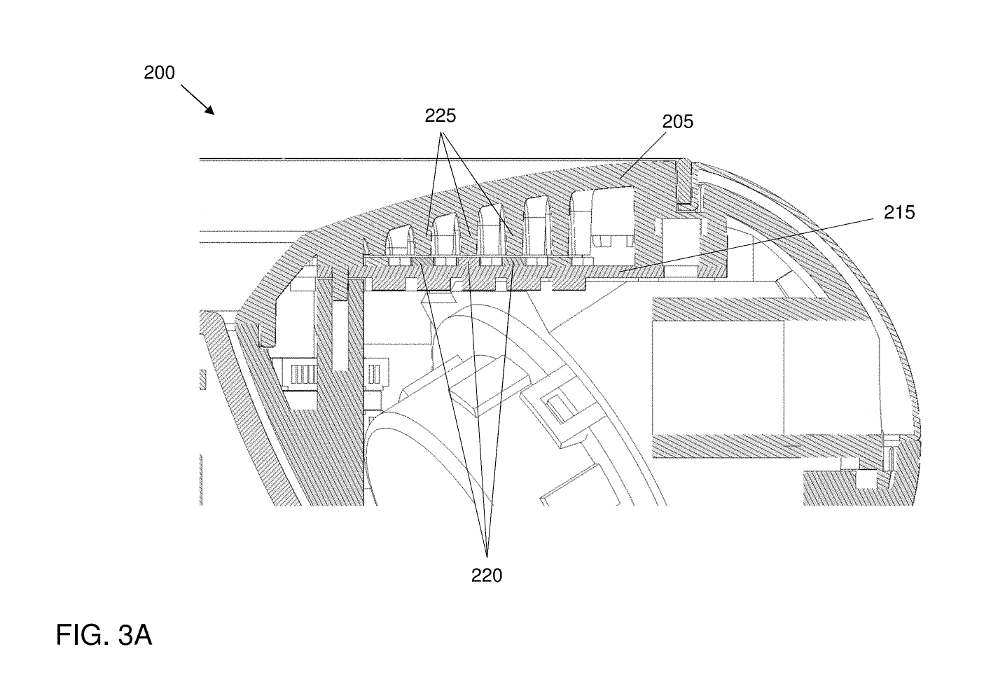

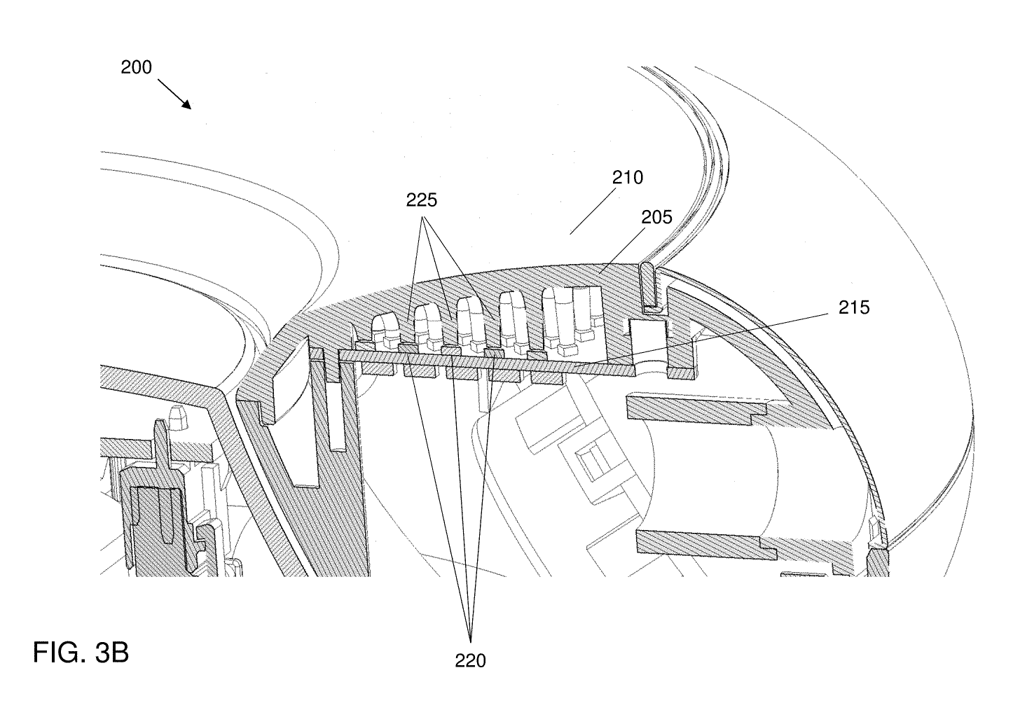

Referring to FIGS. 3A and 3B, there are shown schematically cross-sectional views of the robot 200.

In this example, the display surface 210 of the first layer 205 is curved. The display surface 210 is curved relative to the second layer 215. As such, the display surface 210 is not parallel to the second layer 215. In some examples, the display surface 210 is straight but non-parallel to the second layer 215. The second layer 215 is substantially flat or planar. Where the second layer 215 is annular, the display surface 210 may be a curved annulus. A curved annulus is an annulus having a varying height (the dimension perpendicular to the plane of the annulus). The height of the curved annulus may vary based on the radial distance from the centre of the annulus. A curved annulus may be referred to as a sloped annulus. A curved annulus may correspond to the curved surface of a conical frustum or a partial surface of a torus. As such, the display surface 210 is raised at one end (e.g. at the right hand side of the cross-section shown in FIG. 3A) relative to the other end (e.g. at the left hand side of the cross-section shown in FIG. 3A). The raised end of the display surface 210 corresponds to a radially outer portion of the annular second layer 215.

The display surface 210 may have other shapes in other examples. For example, the display surface 210 may be rectangular or circular. In some examples, the display surface 210 is free-form. A free-form display surface 210 may be manufactured and/or modified according to any desired shape and/or structure.

Since the display surface 210 is curved, the distance between an LED and the display surface 210 may be different for different LEDs. This may have an undesirable effect on the display output, for example where some displayed dots appear differently, e.g. more or less diffuse or saturated, than other displayed dots. One way of increasing the consistency between displayed dots on the display surface 210 would be to curve the second layer 215 such that the second layer 215 is parallel to the display surface 210 across the entirety of the display surface 210. Providing a curved second layer would enable each LED to be the same distance from the display surface 210. However, as described above, the second layer 215 may comprise a PCB to which the plurality of LEDs 220 are connected. It may be relatively complicated to manufacture a curved PCB or to curve an existing planar PCB so as to be parallel with the display surface 210. Even if the LEDs 220 were not disposed on the PCB itself, arranging the LEDs in a curved manner such that there is a uniform distance between each LED and the display surface 210 may be relatively complicated.

In this example, different guide channels in the plurality of guide channels 225 have different channel lengths. The channel length of a guide channel may correspond to the distance between a base end of the guide channel, e.g. the end closest to the respective LED of the guide channel, and a top end of the guide channel, e.g. the end closest to the display surface 210. In some examples, the channel length corresponds to the distance between the respective LED and the display surface 210.

Providing guide channels with different channel lengths enables light travelling from LEDs to the display surface 210 to be guided towards the display surface 210 and displayed in a consistent manner. For example, light emitted from LEDs that are further from the display surface 210 may appear no more diffuse or saturated at the display surface 210 than light emitted from LEDs that are closer to the display surface 210. As such, a visually pleasing array of well-defined and consistent dots may be displayed at the display surface 210 despite the display surface 210 being curved and/or non-parallel relative to the second layer 215.

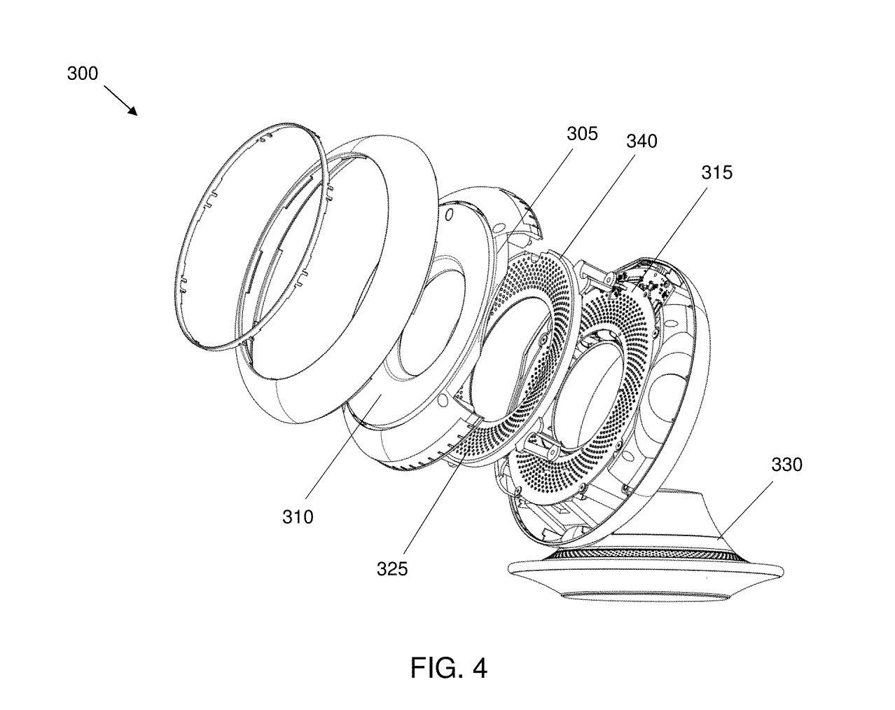

Referring to FIG. 4, there is shown an exploded view of an example of a robot 300. The robot 300 comprises a first layer 305, a second layer 315 and a plurality of guide channels 325. The first layer 305, second layer 315 and guide channels 325 form a display device such as display device 100 described above. The robot 300 also comprises a base portion 330.

In this example, the plurality of guide channels 325 are comprised in a third layer 340. The third layer 340 forms part of the display device. The third layer 340 is arranged between the first layer 305 and the second layer 315. The third layer 340 is separate from the first layer 305. Therefore, in contrast to the robot 200 described above, the plurality of guide channels 325 and the first layer 305 of the robot 300 are formed in separate bodies.

In this example, the plurality of guide channels 325 comprises a plurality of spaced apart apertures. Each aperture comprises a hole or tunnel in the third layer 340. The third layer 340 may be referred to as a ‘light mask’, in that it masks the light travelling from the LEDs in the second layer 315 to the display surface 310.

Providing the guide channels 325 in a separate body increases a flexibility and/or a configurability of the display device compared to a case in which the guide channels and the first layer are integrally formed. For example, the optical properties of the light mask 340 may be selected and/or tuned such that the output displayed on the display surface 310 conforms to desired visual characteristics. Examples of such optical properties include, but are not limited to, transmittance, reflectance and absorption of light having various wavelengths or colors. In some examples, the light mask 340 has a different optical property to the first layer 305. In other examples, the light mask 340 has the same optical properties as the first layer 305.

In some examples, characteristics of the light mask 340 such as the color or material of the light mask 340 are determined based on the optical properties resulting from such characteristics. For example, the material from which the light mask 340 is formed may be selected based on the desired translucency of the given material. Materials having different translucencies may result in displayed outputs having different visual characteristics.

In some examples, the light mask 340 is made from a black colored material. For example, the light mask 340 may be made from black plastic or black rubber. Black colored material may have a relatively low reflectance and/or a relatively high absorption. Using black colored material for the light mask 340 may result in well-defined and clear dots being displayed on the display surface 310, with a relatively low amount of crosstalk and/or saturation between dots compared to dots resulting from a light mask 340 made from white colored material.

In some examples, the light mask 340 is made from white colored material. For example, the light mask 340 may be made from white plastic or white rubber. White colored material may have a relatively high reflectance and/or a relatively low absorption. Using white colored material for the light mask 340 may result in displayed dots that are brighter than those resulting from a light mask 340 made from black colored material. Dots generated via a white colored light mask 340 may have a relatively high amount of crosstalk and/or saturation between dots.

In some examples, different portions of the light mask 340 may have different optical properties. For example, different portions of the light mask 340 may be formed from differently colored materials. Providing different portions of the light mask 340 with different optical properties may be desirable in order to generate a visual output that varies across the display surface 310. For example, a first region of the display surface 310 may display dots that are relatively saturated and a second region of the display surface 310 may display dots that are relatively unsaturated.

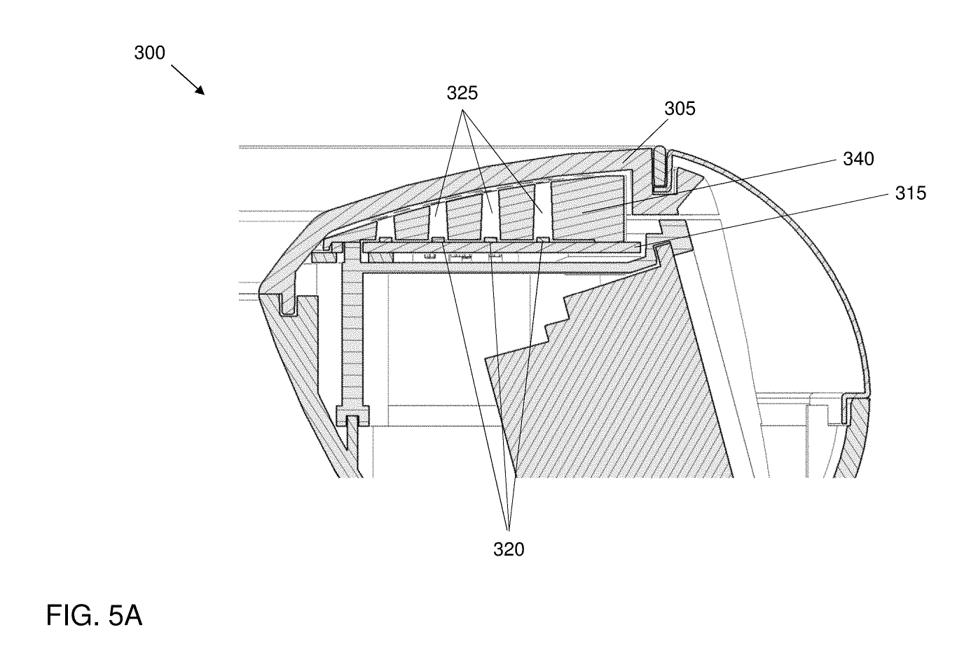

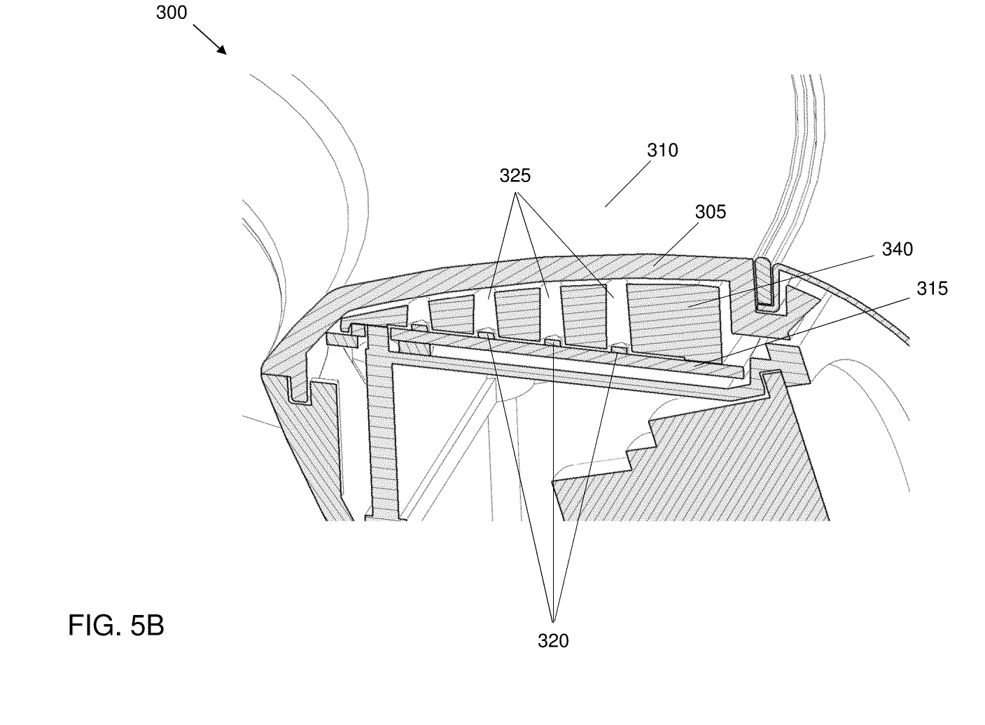

Referring to FIGS. 5A and 5B, there are shown cross-sectional views of the robot 300.

In this example, each of the guide channels 325 comprises a tunnel extending through the third layer 340. Each of the guide channels 325 guides light travelling from a respective LED to the display surface 310.

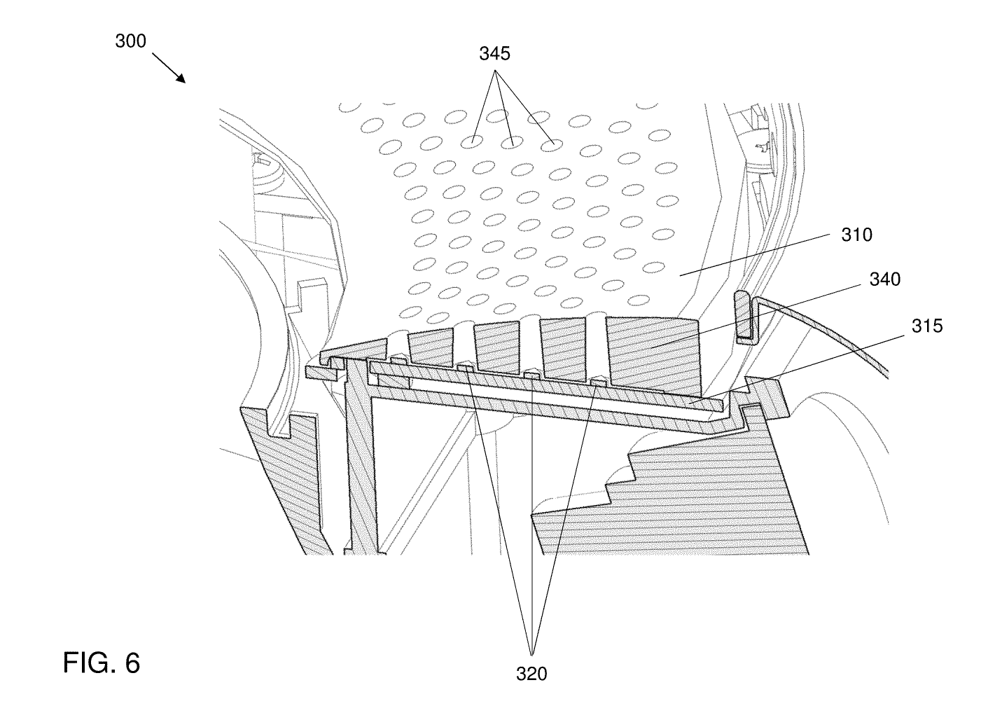

Referring to FIG. 6, there is shown a cross-sectional view of the robot 300.

In this example, the robot 300 is in an activated or light-emitting state. A visual display is output via the display surface 310. The display surface 310 may correspond to an interface between the robot 300 and the environment. The visual display comprises a plurality of dots 345. Each of the plurality of dots 345 corresponds to a different LED in the plurality of LEDs 320 and a different guide channel in the plurality of guide channels 325. The dots 345 may comprise discrete points or shapes. The dots 345 may be regularly or irregularly spaced. The dots 345 may cover the entirety of the display surface 310 or a portion of the display surface 310.

Due to the corresponding guide channel for each individual LED, the displayed dots 345 may be relatively well-defined and clear on the display surface 310. Crosstalk between light emitted from different LEDs may be reduced by using the guide channels 325.

In some examples, the dots 345 are selectively displayed by the robot 300. For example, the robot 300 may be configured to activate some, but not all of the LEDs at a given time.

The robot 300 may be arranged to obtain one or more inputs, for example in the form of input data, signaling and/or stimulus. The robot 300 may be configured to control the plurality of LEDs 320 based on the one or more inputs. The one or more inputs may be received via an input component of the robot 300. The input component may comprise an interface, namely a boundary via which data can be passed or exchanged in one or both directions. In some examples, the input component comprises an input device. An input device comprises a piece of hardware operable to provide the robot 300 with data and/or stimulus. Examples of input components include, but are not limited to, image sensors, proximity sensors, microphones, network interfaces, software components.

The robot 300 may comprise a controller. The controller may be a processor. The controller can include a microprocessor, microcontroller, processor module or subsystem, programmable integrated circuit, programmable gate array, or another control or computing device. The robot 300 may be configured to control the plurality of LEDs 320 using the controller.

The controller may be communicatively coupled to the input component and to the plurality of LEDs 320. The controller may be coupled to the input component and/or to the plurality of LEDs 320 via one or more wires and/or electrical connections.

In some examples, the robot 300 is configured to cause the display output to change in response to a predetermined trigger. Causing the display output to change may comprise causing a first set of LEDs to turn on and a second set of LEDs to turn off. In some examples, causing the display output to change comprises causing a color of light emitted by a given LED to change. For example, the given LED may be a multicolor LED such as a red-green-blue (RGB) LED. The display surface 320 may be arranged to convey information by selectively displaying light from some or all of the plurality of LEDs.

In some examples, the predetermined trigger comprises a user interaction. For example, the predetermined trigger may comprise the robot 300 receiving a voice command. The voice command may be received via an input component, e.g. a microphone, of the robot 300. The robot 300 may respond to the voice command by outputting a control signal, e.g. via the controller of the robot. The control signal causes the display output to change by selectively activating and/or deactivating the plurality of LEDs. The information conveyed by the display surface 320 may vary based on the user interaction.

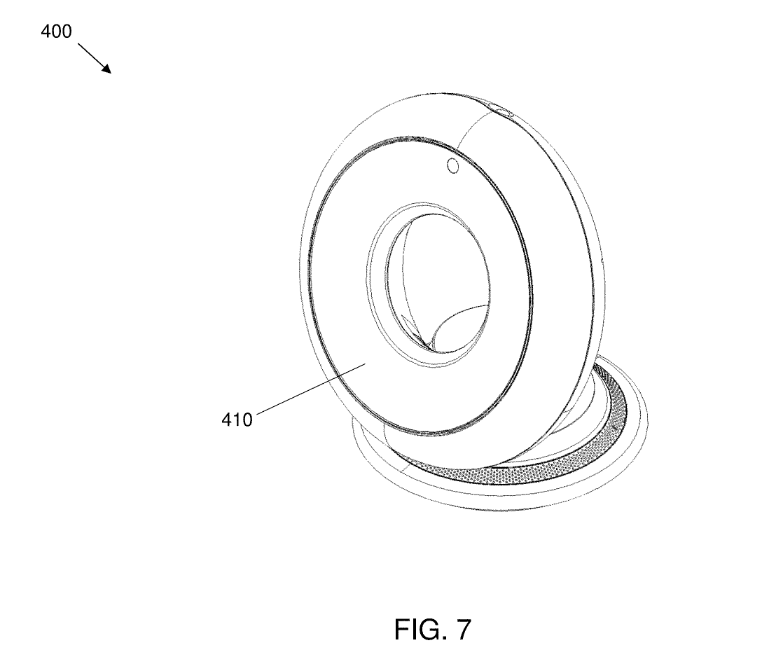

Referring to FIG. 7, there is shown an example of a robot 400.

The robot 400 comprises a display device such as display device 100 described above. The robot 400 comprises a display surface 410 arranged to provide a display output. In this example, the display surface 410 has a sloped annulus shape.

Examples described herein enable a display output to be produced with desired visual properties. A display output with desired visual properties may be produced using a display device comprising an array of discrete light-emitting elements. Examples described herein enable the visual properties of a display output to be adjusted, optimized and/or tuned in a flexible manner Facilitating the output of a display with desired visual properties may enhance the experience of a user of the display device.

Examples described herein enable a display output having desired visual properties to be generated for display devices of varying physical configurations, such as shapes. In some examples described herein, a display surface of a display device is separated from a plurality of light-emitting elements. In some examples, a display surface is curved and/or non-parallel with respect to a plane comprising the light-emitting elements. A displayed output having desired visual properties may be generated using such display devices. The displayed output may be clear, well-defined, adaptable and visually pleasing.

Examples described herein enable a complexity and/or a cost of manufacturing a display device to be reduced. Light travelling from a planar array of LEDs may arrive uniformly and consistently at a non-planar display surface, via the use of multi-length guide channels. As such, there is no need to manufacture a non-planar array of LEDs, e.g. arranged on a printed circuit board, nor to modify an existing planar array of LEDs, processes which may be relatively complicated and/or expensive.

Various measures (for example display devices, robots, optical arrangements and methods) are provided in which a display device comprises a first layer and a second layer. The first layer comprises a display surface facing away from the second layer. The display surface is arranged to provide a display output. The second layer comprises a plurality of light-emitting elements. The display device comprises a plurality of discrete guide channels. Each guide channel in the plurality of guide channels is arranged to guide light travelling from a respective light-emitting element in the plurality of light-emitting elements to the display surface. Providing a corresponding guide channel for each individual light-emitting element facilitates a reduction in an amount of crosstalk between light emitted from different light-emitting elements. Further, an amount of light saturation may be reduced by guiding light travelling from a given light-emitting element to the display surface. As such, the display output produced on the display surface may conform to desired visual parameters.

In some examples, at least part of the display surface is curved relative to the second layer. In some examples, the second layer is substantially planar. In some examples, different guide channels in the plurality of guide channels have different channel lengths. As such, light may arrive in a substantially uniform manner at the display surface from the plurality of light-emitting elements, even when the display surface is curved relative to the second layer and/or when the display surface and the second layer are non-parallel.

In some examples, the first layer and the second layer are spaced apart. As such, light travelling from the second layer may be guided to the first layer via one or more intermediate layers.

In some examples, the plurality of guide channels and the first layer are integrally formed. Providing the guide channels and the first layer in a single body may result in simpler manufacturing and/or fewer overall components compared to a case in which the guide channels are provided in a separate body to the first layer.

In some examples, the plurality of guide channels comprises a plurality of spaced apart solid elongate members. A given surface of each of the plurality of guide channels may be formed of a white colored material or treated with a white colorant. The given surface of each of the plurality of guide channels may be treated with a silver colorant and/or a black colorant. The treatment of the given surface may be selected to provide desired visual characteristics of the display output.

In some examples, the plurality of guide channels and the first layer are formed in separate bodies. Providing the guide channels in a separate body to the first layer may facilitate an increase a flexibility and/or an adjustability in the visual properties of the display output.

In some examples, the plurality of guide channels comprises a plurality of spaced apart apertures. As such, light from a single LED in an array of LEDs may be guided through a corresponding aperture. Separating the apertures, e.g. using opaque material, reduces an amount of crosstalk between light emitted from different LEDs.

In some examples, the plurality of guide channels are comprised in a third layer of the display device. The third layer is arranged between the first layer and the second layer. The third layer may comprise a light mask layer. Providing the guide channels in a separate light mask layer facilitates an increase in the adjustability of the visual or optical characteristics of the display output. For example, the material, color and/or treatment of the light mask layer may be optimized so as to facilitate a display output having desired properties.

In some example, the third layer has a different optical property to the first layer. As such, the third layer may be tuned and/or adjusted independently of the first layer. In some examples, the third layer is made from a black colored material. In some examples, the third layer is made from a white colored material. In some examples, the third layer is made from plastic. In some examples, the third layer is made from rubber.

In some examples, the plurality of light-emitting elements comprises a plurality of LEDs. As such, an amount of crosstalk and/or saturation of light arriving at a display surface from a plurality of LEDs may be reduced.

In some examples, at least part of the first layer is translucent. The translucent part of the first layer allows light to pass through the first layer in a controlled manner.

In some examples, the first layer comprises a light diffuser. The light diffuser may act to soften the visual output of the display surface. As such, a user may not be able to identify that the visual output displayed on the display surface is in fact caused by a specific type of light-emitting element such as an LED.

In some examples, the display surface has a curved annulus shape. In some examples, the display surface is a partial surface of a torus. In some examples, the display surface is free-form. In some examples, the second layer is annular. As such, a display output having desired visual properties may be generated on a curved display surface.

In some examples, the display device is configured to cause the display output to change in response to a predetermined trigger. The predetermined trigger may comprise a user interaction. The predetermined trigger may comprise the display device receiving a voice command.

In some examples, the display device is comprised in a robot. As such, the display output provided on the display surface may form part of an interaction between the robot and a user. For example, the display output may be generated in response to a command and/or request from a user. The display output may vary depending on the command and/or request.

The above embodiments are to be understood as illustrative examples. Further embodiments are envisaged.

In examples described above, the second layer comprises a plurality of light-emitting elements. In other examples, the second layer comprises a plurality of light-receiving elements. The light-receiving elements may, for example, comprise cameras or sensors such as charge-coupled device (CCD) or complementary metal-oxide-semiconductor (CMOS) sensors. Light may be guided from the environment of the device to the light-receiving elements via the plurality of guide channels. As such, light may be received at the light-receiving elements in a consistent manner, even when different light-receiving elements are positioned at different distances from the outer surface of the device.

It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

What is claimed is:

1. A display device comprising first, second and third layers, the first layer being spaced apart from the second layer and the third layer being arranged between the first and second layers, the first layer comprising a display surface facing away from the second layer, the display surface being arranged to provide a display output, the second layer comprising a plurality of light-emitting elements, the third layer of the display device comprising a plurality of discrete guide channels, each guide channel in the plurality of guide channels being arranged to guide light travelling from a respective light-emitting element in the plurality of light-emitting elements to the display surface, wherein different guide channels in the plurality of guide channels have different channel lengths.

2. The display device of claim 1, wherein at least part of the display surface is curved relative to the second layer.

3. The display device of claim 1, wherein the second layer is substantially planar.

4. The display device of claim 1, wherein the display surface is non-parallel to the second layer.

5. The display device of claim 1, wherein the plurality of guide channels and the first layer are integrally formed or wherein the plurality of guide channels and the first layer are formed in separate bodies.

6. The display device of claim 1, wherein the third layer comprises a light mask layer.

7. The display device of claim 1, wherein the third layer has a different optical property to the first layer.

8. The display device of claim 7, wherein the third layer is made from a black coloured material or is made from a white coloured material.

9. The display device of claim 7, wherein the third layer is made from plastic or is made from rubber.

10. The display device of claim 1, wherein the plurality of guide channels comprises a plurality of spaced apart solid elongate members or comprises a plurality of spaced apart apertures.

11. The display device of claim 1, wherein a given surface of each of the plurality of guide channels:
is formed of a white coloured material or is treated with a white colorant; and/or
is treated with a silver colorant and/or a black colorant.

12. The display device of claim 1, wherein at least part of the first layer is translucent.

13. The display device of claim 1, wherein the first layer comprises a light diffuser.

14. The display device of claim 1, wherein the second layer is annular.

15. The display device of claim 1, wherein the second layer comprises a printed circuit board.

16. The display device of claim 1, wherein the display surface has a curved annulus shape and/or wherein the display surface is free-form.

17. The display device of claim 1, wherein the display device is configured to cause the display output to change in response to a predetermined trigger, and wherein the predetermined trigger comprises:
a user interaction; and/or
the display device receiving a voice command.

18. The display device of claim 1, wherein the display device is comprised in a robot.

19. A robot comprising a display device, the display device comprising a first layer and a second layer, the first layer comprising a display surface facing away from the second layer, the display surface being arranged to provide a display output, the second layer comprising a plurality of light-emitting elements, wherein the display device comprises a plurality of discrete guide channels, each guide channel in the plurality of guide channels being arranged to guide light travelling from a respective light-emitting element in the plurality of light-emitting elements to the display surface.

20. A display device comprising a first layer and a second layer, the first layer comprising a display surface facing away from the second layer, the display surface being arranged to provide a display output, the second layer comprising a plurality of light-emitting elements and facing an inner surface of the first layer, wherein the display device comprises a plurality of discrete guide channels, each guide channel in the plurality of guide channels being arranged to guide light travelling from a respective light-emitting element in the plurality of light-emitting elements to the display surface, wherein different guide channels in the plurality of guide channels have different channel lengths.
